(19) United States
(12) Patent Application Publication
(10) Pub. No.: US 2025/0292860 A1
(43) Pub. Date: Sep. 18, 2025

(54) DETERMINING READ LEVELS USING REFERENCE DATA

(71) Applicant: Micron Technology, Inc., Boise, ID (US)

(72) Inventors: Wenchi Hong, Zhubei City (TW); Chin Yin Tsai, Zhubei City (TW); Yi Lin Lai, Zhubei City (TW); Chungan Hsu, Zhubei City (TW)

(21) Appl. No.: 19/070,207

(22) Filed: Mar. 4, 2025

Related U.S. Application Data
(60) Provisional application No. 63/564,792, filed on Mar. 13, 2024.

(51) Int. Cl. G11C 29/52; G11C 16/08; G11C 16/26

(52) U.S. Cl. CPC G11C 29/52; G11C 16/08; G11C 16/26

(57) ABSTRACT

Methods, systems, and apparatuses include retrieving reference data for a memory device. A read margin is scanned by determining sense data and pre-sense data for read levels of the read margin by applying a threshold voltage at each read level to cells of the memory device. A total error count is calculated by the memory device for each read level using the sense data, the pre-sense data, and the reference data. An optimal read level is selected for the read margin in response to comparing the total error count for each read level and determining a read level that has a lowest total error count.

### CROSS-REFERENCE TO RELATED APPLICATION

The present application claims the benefit of U.S. Provisional Patent Application No. 63/564,792 filed on Mar. 13, 2024, which is incorporated by reference herein in its entirety.

### TECHNICAL FIELD

The present disclosure generally relates to determining read levels, and more specifically, relates to determining read levels using reference data.

### BACKGROUND ART

A memory subsystem can include one or more memory devices that store data. The memory devices can be, for example, non-volatile memory devices and volatile memory devices. In general, a host system can utilize a memory subsystem to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory subsystem in accordance with some embodiments of the present disclosure.

FIG. 2 illustrates an example computing system that includes a read level determination component in accordance with some embodiments of the present disclosure.

FIG. 3 is a flow diagram of an example method to determine optimal read levels using reference data in accordance with some embodiments of the present disclosure.

FIG. 4 is another flow diagram of an example method to determine optimal read levels using reference data in accordance with some embodiments of the present disclosure.

FIG. 5 is another flow diagram of an example method to determine optimal read levels using reference data in accordance with some embodiments of the present disclosure.

FIG. 6 is a block diagram of an example computer system in which embodiments of the present disclosure may operate.

### DETAILED DESCRIPTION

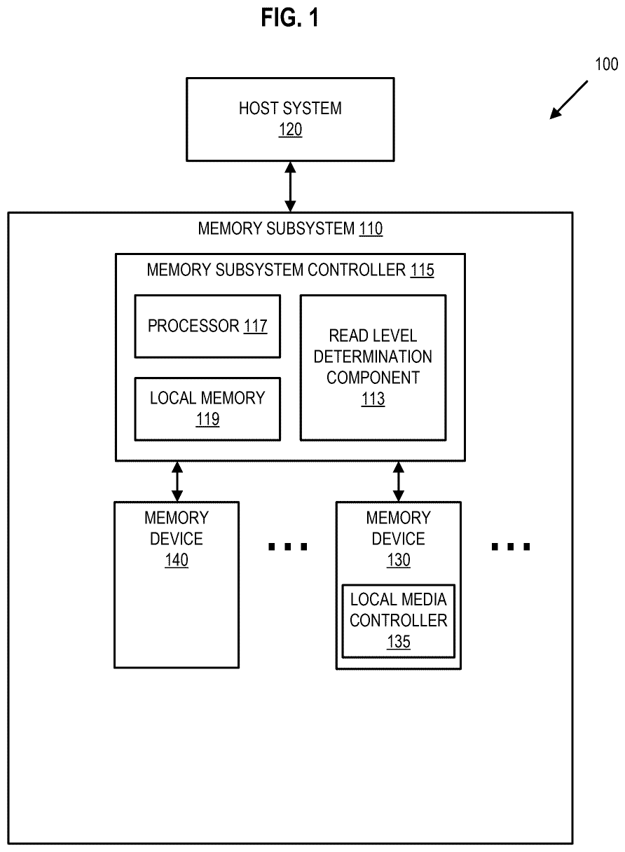

Aspects of the present disclosure are directed to determining optimal read levels using reference data in a memory subsystem. A memory subsystem can be a storage device, a memory module, or a hybrid of a storage device and memory module. Examples of storage devices and memory modules are described below in conjunction with FIG. 1. In general, a host system can utilize a memory subsystem that includes one or more components, such as memory devices that store data. The host system can provide data to be stored at the memory subsystem and can request data to be retrieved from the memory subsystem.

A memory device can be a non-volatile memory device. A non-volatile memory device is a package of one or more dice. One example of non-volatile memory devices is a negative-and (NAND) memory device. Other examples of non-volatile memory devices, including NAND flash memory devices, are described below in conjunction with FIG. 1. The dice in the packages can be assigned to one or more channels for communicating with a memory subsystem controller. Each die can consist of one or more planes. Planes can be grouped into logic units identified by a logical unit number (LUN). For some types of non-volatile memory devices (e.g., NAND memory devices), each plane consists of a set of physical blocks, which are groups of memory cells to store data. A cell is an electronic circuit that stores information.

Depending on the cell type, a cell can store one or more bits of binary information, and has various logic states that correlate to the number of bits being stored. The logic states can be represented by binary values, such as “0” and “1”, or combinations of such values. There are various types of cells, such as single-level cells (SLCs), multi-level cells (MLCs), triple-level cells (TLCs), quad-level cells (QLCs), and penta-level cells (PLCs). For example, an SLC can store one bit of information and has two logic states while a QLC can store four bits of information and has sixteen logic states.

In conventional memory systems, memory devices degrade with time, making it difficult to read the correct stored values. For example, a memory cell can experience charge loss, potentially changing the value read from the memory cell when reading the cell using the threshold voltage for the memory cell when programmed. The threshold voltage applied to the memory cells during reading is referred to as the read level. Higher density memory cells (e.g., MLCs, TLCs, QLCs, and PLCs) have multiple read levels to account for the increased number of logic states. For example, while a single read level can be used to read SLC memory cells (e.g., a read level between the voltage distributions for a 0 bit and 1 bit), more read levels are needed to read MLC memory cells. Higher density memory has voltage distributions that represent the data stored in memory cells for each logic state. The space between these voltage distributions is a read margin. Failing to account for a shift in these voltage distributions due to the charge loss and corresponding change in the read margin of the memory cells can lead to an increase in read errors (e.g., raw bit error rate (RBER). Conventional memory systems address this by measuring an amount of shift in read levels and adjusting the read levels to reduce RBER. For example, conventional memory systems measure the shifted voltage signal for one read level using iterative read levels on a large sample of memory cells and shift the remaining read levels based on this shifted voltage signal. Alternatively, conventional memory system determine a shift in read levels using read sample offsets (e.g., the measured shift in read levels) and error correction codes (ECC) to get valley statistics for the read levels, such as error counts, relative valley widths, and measured offsets. These approaches, however, are computation heavy in the number of reads needed and/or the use of error correcting codes, resulting in lower performance and excess energy consumption.

Aspects of the present disclosure address these and other deficiencies by determining optimal read levels using a read of known reference data that amounts to a very limited subset of memory cells in a memory device. For example, the memory system can sweep read levels in a read margin to determine sensed values of the reference data and use a hardware accelerator to determine error counts for each of the swept read levels. The memory system therefore compares the error counts for the different read levels in the sweep and determines the optimal read level for that read margin. By bypassing the memory controller's reading of stored values and the more computationally intensive ECC approach, the memory subsystem determines read levels in less time and using less energy.

FIG. 1 illustrates an example computing system 100 that includes a memory subsystem 110 in accordance with some embodiments of the present disclosure. The memory subsystem 110 can include media, such as one or more volatile memory devices (e.g., memory device 140), one or more non-volatile memory devices (e.g., memory device 130), or a combination of such.

A memory subsystem 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory subsystems 110. In some embodiments, the host system 120 is coupled to different types of memory subsystems 110. FIG. 1 illustrates one example of a host system 120 coupled to one memory subsystem 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processing device such as a processor chipset and a software stack executed by the processor chipset. The processor chipset can include one or more cores, one or more caches, a memory controller (e.g., NVDIMM controller), and/or a storage protocol controller (e.g., a peripheral component interconnect express (PCIe) controller, a serial advanced technology attachment (SATA) controller). The host system 120 uses the memory subsystem 110, for example, to write data to the memory subsystem 110 and read data from the memory subsystem 110.

The host system 120 can be coupled to the memory subsystem 110 via a physical host interface. Examples of a physical host interface include, but are not limited to, a SATA interface, including a mini-SATA (mSATA) interface, a PCIe interface, including a mini PCIe (mPCIE) interface, a Non-Volatile Memory Express (NVMe) interface, a universal serial bus (USB) interface, an a Fibre Channel, Serial Attached SCSI (SAS), a Small Computer System Interface (SCSI), a double data rate (DDR) memory bus, a dual in-line memory module (DIMM) interface (e.g., DIMM socket interface that supports Double Data Rate (DDR)), an Advanced Host Controller (AHCI) interface, an Open NAND Flash Interface (ONFI) interface, a Double Data Rate (DDR) interface, a Low Power Double Data Rate (LPDDR) interface, any other interface, and/or combinations of these interfaces. The physical host interface can be used to transmit data between the host system 120 and the memory subsystem 110. The host system 120 can further utilize an NVMe interface to access components (e.g., memory devices 130 and 140) when the memory subsystem 110 is coupled with the host system 120 by the PCIe interface. The physical host interface can provide an interface for passing control, address, data, and other signals between the memory subsystem 110 and the host system 120. FIG. 1 illustrates a memory subsystem 110 as an example. In general, the host system 120 can access multiple memory subsystems via the same communication connection, multiple separate communication connections, and/or a combination of communication connections.

The memory devices 130 and 140 can include any combination of the different types of non-volatile memory devices and/or volatile memory devices. The volatile memory devices (e.g., memory device 140) can be, but are not limited to, random-access memory (RAM), such as dynamic random-access memory (DRAM), synchronous dynamic random-access memory (SDRAM), video random-access memory (VRAM), and cache memory.

Some examples of non-volatile memory devices (e.g., memory device 130) include negative-and (NAND) type flash memory devices and write-in-place type memory devices, such as a three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write-in-place operation, where a non-volatile memory cell can be programmed without the non-volatile memory cell being previously erased. NAND type flash memory includes, for example, two-dimensional NAND (2D NAND) and three-dimensional NAND (3D NAND).

Although non-volatile memory devices such as NAND type memory (e.g., 2D NAND, 3D NAND) and 3D cross-point array of non-volatile memory cells are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random-access memory (FeRAM), magneto random-access memory (MRAM), Spin Transfer Torque (STT)-MRAM, nano-RAM (NRAM), silicon-oxide-nitride-oxide-silicon (SONOS) memory, conductive bridging RAM (CBRAM), resistive random-access memory (RRAM), oxide based RRAM (OxRAM), negative-or (NOR) flash memory, and erasable programmable read-only memory (EPROM), including electrically erasable programmable read-only memory (EEPROM).

A memory subsystem controller 115 (or controller 115 for simplicity) can communicate with the memory device 130 to perform operations such as reading data, writing data, or erasing data at the memory device 130 and other such operations (e.g., in response to commands scheduled on a command bus by controller 115). The memory subsystem controller 115 can include hardware such as one or more integrated circuits and/or discrete components, a buffer memory, or a combination thereof. The hardware can include digital circuitry with dedicated (i.e., hard-coded) logic to perform the operations described herein. The buffer memory of subsystem controller 115 can include any of the volatile or non-volatile memory types mentioned above including combinations thereof. The memory subsystem controller 115 can be a microcontroller, special purpose logic circuitry (e.g., a field programmable gate array (FPGA), an application specific integrated circuit (ASIC), etc.), or another suitable processor.

The memory subsystem controller 115 can include a processing device 117 (processor) configured to execute instructions stored in memory subsystem 110 (e.g., stored in a local memory 119). In some examples, the local memory 119 of the memory subsystem controller 115 includes an embedded memory configured to store instructions for performing various processes, operations, logic flows, and routines that control operation of the memory subsystem 110, including handling communications between the memory subsystem 110 and the host system 120.

In some embodiments, the local memory 119 can include memory registers storing memory pointers, fetched data, etc. The local memory 119 can also include read-only memory (ROM) for storing micro-code. While the example memory subsystem 110 in FIG. 1 has been illustrated as including the memory subsystem controller 115, in another embodiment of the present disclosure, a memory subsystem 110 does not include a memory subsystem controller 115, and can instead rely upon external control (e.g., provided by an external host, or by a processing device or controller separate from the memory subsystem 110).

In general, the memory subsystem controller 115 can receive commands or operations from the host system 120 and can convert the commands or operations into instructions or appropriate commands to achieve the desired access to the memory devices (e.g., memory devices 130 and/or 140. The memory subsystem controller 115 can be responsible for other operations such as wear leveling operations, garbage collection operations, error detection and error-correcting code (ECC) operations, encryption operations, caching operations, and address translations between a logical address (e.g., logical block address (LBA) and/or namespace) and a physical address (e.g., physical block address) that are associated with the memory devices (e.g., memory devices 130 and/or 140). The memory subsystem controller 115 can further include host interface circuitry to communicate with the host system 120 via the physical host interface. The host interface circuitry can convert the commands received from the host system into command instructions to access the memory devices (e.g., memory devices 130 and/or 140) as well as convert responses associated with the memory devices into information for the host system 120.

The memory subsystem 110 can also include additional circuitry or components that are not illustrated. In some embodiments, the memory subsystem 110 can include a cache or buffer (e.g., DRAM) and address circuitry (e.g., a row decoder and a column decoder) that can receive an address from the memory subsystem controller 115 and decode the address to access the memory devices (e.g., memory devices 130 and/or 140).

In some embodiments, the memory devices (e.g., memory devices 130 and/or 140) include local media controllers 135 that operate in conjunction with memory subsystem controller 115 to execute operations on one or more memory cells of the memory devices (e.g., memory devices 130 and/or 140). An external controller (e.g., memory subsystem controller 115) can externally manage the memory devices (e.g., perform media management operations on the memory devices 130 and/or 140). In some embodiments, a memory device (e.g., memory device 130) is a managed memory device, which is a raw memory device combined with a local controller (e.g., local controller 135) for media management within the same memory device package. An example of a managed memory device is a managed NAND (MNAND) device.

The memory subsystem 110 includes a read level determination component 113 that determines an optimal read level using reference data. In some embodiments, the controller 115 includes at least a portion of the read level determination component 113. For example, the controller 115 can include a processing device 117 configured to execute instructions stored in local memory 119 for performing the operations described herein. In some embodiments, a read level determination component 113 is part of the host system 120, an application, or an operating system.

The read level determination component 113 determines optimal read levels by sweeping read levels, determining error counts for each read level using reference data, and determining an optimal read level using the error counts. Further details with regards to the operations of the read level determination component 113 are described below.

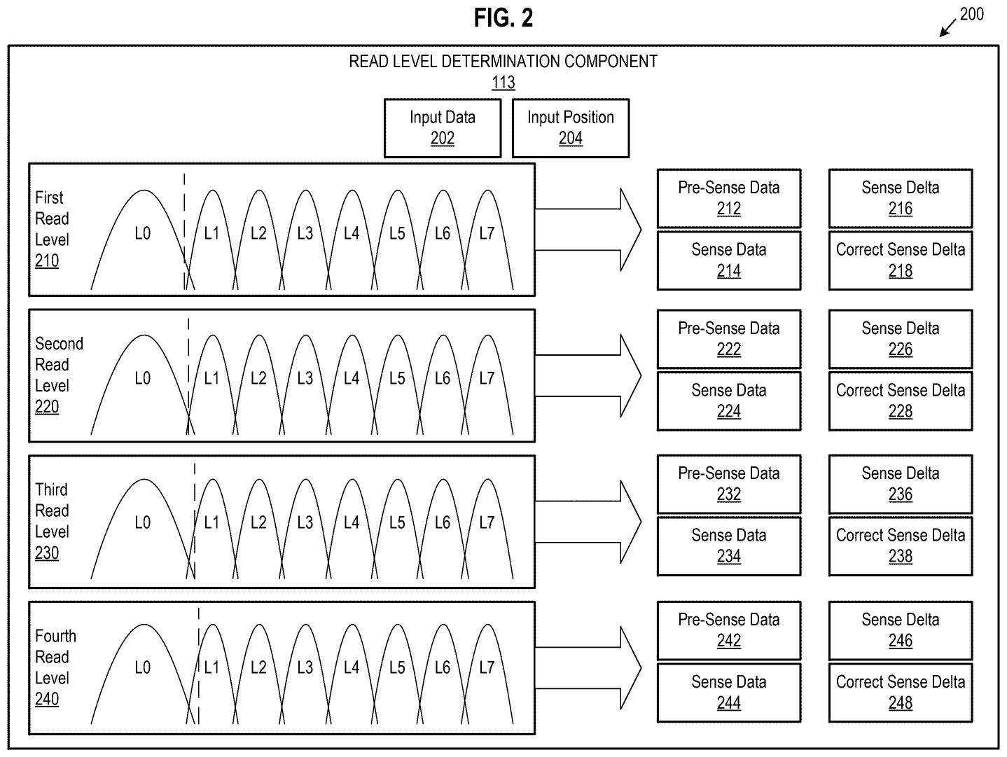

FIG. 2 illustrates an example computing system 200 that includes a read level determination component 113 in accordance with some embodiments of the present disclosure. As shown in FIG. 2, read level determination component 113 performs a valley check of the read margin between logic states L0 and L1. For example, read level determination component 113 sweeps read levels (e.g., first read level 210, second read level 220, third read level 230, and fourth read level 240) to determine an optimal read level for the read margin using reference data. Although only one valley check is illustrated, in some embodiments, read level determination component 113 performs valley checks of additional read margins for other sets of logic states. For example, read level determination component 113 sweeps read levels of a second margin to determine an optimal read level for the second read margin using the reference data. FIG. 2 illustrates example voltage distributions of logic states for a memory device (e.g., memory device 130 of FIG. 1).

The reference data is programmed into a memory device of the memory subsystem. For example, the reference data is stored in a one-time programmable (OTP) area of a memory device (e.g., memory device 130) during manufacturing of the memory device. Since the OTP area is programmable a single time, it has higher reliability and less susceptibility to charge loss than the general area of the memory device. The reference data may be sequential data and/or random data. The illustrated logic states L0, L1, L2, L3, L4, L5, L6, and L7 represent voltage distributions of data stored in the memory device. For example, as explained above, a memory cell being in an L0 state corresponds with the memory cell storing a value of 111, with L1-L7 corresponding with values of 110, 100, 000, 010, 011, 001, and 101, respectively. As shown in FIG. 2, the voltage distributions for the logic states L0-L7 may have some overlap due to charge loss, memory defects, etc. For example, although a memory cell was programmed to be in an L0 state, its actual voltage may be higher than a memory cell programmed to be in an L1 state. Because read level determination component 113 uses known reference data, read level determination component 113 can detect which memory cells that store the known reference data are read in error at various read levels and, therefore, determine an optimal read level between the two distributions (e.g., L0 and L1) using error counts, as explained in further detail below. Although FIG. 2 illustrates read level determination component 113 performing valley checks on a memory device composed of TLC cells (e.g., having eight logic states), read level determination component 113 can perform valley checks on memory devices with any memory cell density (e.g., any number of logic states) and/or combination of memory cell densities.

The memory device stores the known reference data in input data 202. For example, the reference data is read from the OTP area of the memory device and stored in the limited set of memory cells of the memory device. In some embodiments, read level determination component 113 determines the limited set of memory cells using input position 204. For example, input position 204 is a line buffer that marks relevant memory cells (e.g., memory cells that we want to determine optimal read levels for), allowing read level determination component 113 to filter out unnecessary areas of memory. In some embodiments, read level determination component 113 determines input position 204 using an array address. For example, read level determination component 113 receives an array address indicating logical units of memory and determines input position 204 according to the receive array address. In one example, input position 204 includes a ‘1’ for each relevant position such that performing a logical AND operation using sense data 214 and input position 204 results in sense data for the relevant limited set of memory cells.

As shown in FIG. 2, read level determination component 113 performs a sense operation on a first read level 210 of a read margin for a limited set of memory cells of a memory device (e.g., memory device 130 of FIG. 1) to determine sense data 214 for the limited set of memory cells. In some embodiments, the limited set of memory cells is a smaller size than the number of memory cells targeted by a read operation. For example, the limited set of memory cells is 1 kilobyte of data and a number of cells targeted by a read operation is 4 kilobytes. By targeting a smaller portion of memory, read level determination component 113 is able to determine optimal read levels more efficiently.

In some embodiments, sense data 214 is a line buffer storing the results of the sense operation on the limited set of memory cells for the read level, where a bit of the line buffer corresponds with the result of the sense operation for a memory cell at the given read level. Although FIG. 2 illustrates read level determination component 113 performing valley checks on a single read margin, read level determination component 113 can perform similar operations to determine optimal read levels for any read margin and therefore any bit of the limited set of memory cells.

In some embodiments, read level determination component 113 determines sense data 214 for a memory cell based on the read margin and whether first read level 210 is greater than the threshold voltage of the programmed memory cell. For example, for the read margin between L0 and L1, read level determination component 113 determines that sense data 214 for the memory cell is ‘111’ if first read level 210 turns on the channel for the memory cell and determines that sense data 214 for the memory cell is ‘110’ of first read level 210 does not turn on the channel for the memory cell (while logic states L1-L7 should all result in the channel not activating for first read level 210, for the purposes of read level determination for the read margin between L0 and L1, read level determination component 113 can treat sense data 214 as falling into logic state L0 or logic state L1). However, there can be bits read in error due to charge loss, imperfections in memory, etc.

Read level determination component 113 determines sense delta 216 using pre-sense data 212 and sense data 214. Pre-sense data 212 is sense data from a sense operation at a prior read level. For example, for second read level 220, pre-sense data 222 is sense data 214 from first read level 210. Similarly, pre-sense data 232 is sense data 224 from second read level 220 and pre-sense data 242 is sense data 234 from third read level 230. In some embodiments, such as when performing a sense operation at first read level 210 (e.g., with no prior read levels), read level determination component 113 uses a predetermined pre-sense data 212. For example, read level determination component 113 sets pre-sense data 212 as all ‘0’s.

Read level determination component 113 determines sense delta 216 as the difference between the value sensed at the current read level and the value sensed at a previous read level. For example, read level determination component 113 determines sense delta 216 for first read level 210 by performing a logical XOR operation using sense data 214 and pre-sense data 212. In such an embodiment, sense delta 216 indicates bits that changed since the previous read level. Accordingly, the number of ‘1’s in sense delta 216 is the number of sensed bits with a value of ‘1’ within the relevant range (e.g., between the previous read level and the current read level). In other words, sense delta 216 indicates the number of memory cells that were sensed within the current read margin slice (e.g., area between the previous and current read levels). Read level determination component 113 determines sense deltas 226, 236, and 246 for second read level 220, third read level 230, and fourth read level 240 respectively using the respective pairs of sense data 224, 234, and 244 and pre-sense data 222, 232, and 242. As the read levels increase, memory cells programmed in the L1 state will be erroneously included in the read margin slices (e.g., for second read level 220, third read level 230, and fourth read level 240). Accordingly, for these read levels, sense deltas 226, 236, and 246 will include ‘1’s for memory cells that were originally programmed in both L0 and L1 logic states.

Read level determination component 113 calculates correct sense delta 218 for first read level 210 using input data 202 and sense delta 216. Correct sense delta 218 indicates which of the sensed bits with a value of ‘1’ in sense delta 216 are correct using input data 202 as a ground truth. In other words, correct sense delta 218 indicates the number of bits that are correctly sensed as being in L0 for the current read margin slice (e.g., area between the previous and current read margins). As the read levels increase, memory cells programmed in the L1 logic state will be included in the read margin slices (e.g., for second read level 220, third read level 230, and fourth read level 240). However, because correct sense deltas 218, 228, 238, and 248 are calculated based on input data 202, correct sense deltas 218, 228, 238, and 248 will include ‘1’s only for memory cells correctly sensed in an L0 logic state between the previous and current read level. In some embodiments, correct sense delta 218 is a line buffer with a ‘1’ for every ‘1’ in sense delta 216 that is correct.
Read level determination component 113 compares sense delta 216 with input data 202 for the limited set of memory cells (e.g., indicated by input position 204) and calculates correct sense delta 218 based on the comparison. For example, read level determination component 113 calculates correct sense delta 218 by performing logical operations executed by a hardware accelerator of the memory subsystem (e.g., logical operations implemented in purpose-specific hardware within read level determination component 113 rather than firmware and/or processing device 117 of memory subsystem 110 of FIG. 1). In one embodiment, read level determination component 113 performs a logical AND operation using input data 202 and sense delta 216 to calculate correct sense delta 218. In one embodiment, read level determination component 113 converts sense data 214 to a binary value for comparison. For example, a “1” in sense delta 216 indicates that the corresponding memory cell is storing a binary value of “111.” Read level determination component 113 converts the “1” to “111” to compare the binary value of the sensed memory cell to the corresponding binary value stored input data 202. In other embodiments, read level determination component 113 converts input data 202 to single bit values for the comparison. For example, read level determination component 113 converts values of “111” to “1” and other values to “0” to compare input data 202 as a single bit value with the single bit value of sense delta 216. The result of this operation includes a ‘1’ wherever the bits of input data 202 and sense delta 216 match and a ‘0’ otherwise. Accordingly, sense delta 216 includes a ‘1’ value for all memory cells programmed to an L0 state within the current read margin slice and can indicate when, e.g., the margin slice of the current read level adds no additional correctly sensed L0 values.

In some embodiments, read level determination component 113 calculates a total error count using sense delta 216, correct sense delta 218, and input data 202. Read level determination component 113 calculates a final correct count value for all read levels as the total number of memory cells in logic state L0 based on the known reference data. For example, read level determination component 113 determines the correct number of memory cells in logic state L0 using input data 202.

Read level determination component 113 calculates a cumulative correct sense count for first read level 210 as the number of memory cells correctly sensed in logic state L0 up to first read level 210 using correct sense delta 218. For example, the number of ‘1’s in correct sense delta 218 indicates the number of memory cells correctly sensed as belonging to logic state L0 for first read level 210. Because there are no read levels prior to first read level 210, the cumulative correct sense count is equal to the number of ‘1’s in correct sense delta 218. For higher read levels, read level determination component 113 calculates the cumulative correct sense count as the sum of the number of ‘1’s for all correct sense deltas up to the current read level. For example, read level determination component 113 calculates the cumulative correct sense count for fourth read level 240 as the sum of the number of ‘1’s in correct sense deltas 218, 228, 238, and 248. In one embodiment, read level determination component 113 uses the cumulative correct sense count to set the final correct count value. For example, when read level determination component 113 detects a correct sense delta for a given read level that adds no new correctly sensed memory cells (e.g., correct sense delta is equal to zero), read level determination component 113 determines that all memory cells in programmed in the current logic state have been sensed and the cumulative correct sense count is the final correct count value.

Read level determination component 113 calculates a cumulative incorrect sense count for first read level 210 as the number of memory cells incorrectly sensed in logic state L0 up to first read level 210 (e.g., the number of memory cells programmed in logic state L1 but incorrectly sensed at first read level 210 as belonging to logic state L0). For example, read level determination component 113 performs a logical XOR operation using sense delta 216 and correct sense delta 218 and determines an incorrect sense count for first read level 210 as the number of ‘1’s in the result of a logical XOR operation. Because there are no read levels prior to first read level 210, the cumulative incorrect sense count is equal to the incorrect sense count for first read level 210. For higher read levels, read level determination component 113 calculates the cumulative incorrect sense count as the sum of the number of ‘1’s for all incorrect sense counts up to the current read level. For example, read level determination component 113 calculates the cumulative incorrect sense count for fourth read level 240 as the sum of the number of ‘1’s in the result of the logical XOR operation between pairs of sense deltas 216, 226, 236, and 246 and correct sense deltas 218, 228, 238, and 248.

Read level determination component 113 calculates a total error count for first read level 210 using the final correct count, the cumulative correct sense count for first read level 210, and the cumulative incorrect sense count for first read level 210. The difference between the final correct count and the cumulative correct sense count is the number of memory cells programmed to the L0 logic state that were not sensed at first read level 210. Read level determination component 113 adds this value to the incorrect sense count to get the total error count. In some embodiments, read level determination component 113 calculates total error count according to the following equation: TotalErrorCount=(FinalCorrectCount−CumulativeCorrectSenseCount)+CumulativeIncorrectSenseCount. Because the final correct count will remain the same for all read levels, the term (FinalCorrectCount−CumulativeCorrectSenseCount) will decrease as the number of correctly sensed L0 memory cells increases. In contrast, the term CumulativeIncorrectSenseCount will increase as the number of incorrectly sensed L1 memory cells increases. The total error count will therefore be the smallest where there is the least amount of overlap between the logic states. In some embodiments, read level determination component 113 stores the total error count for the read level for future use in determining the optimal read level.

In some embodiments, read level determination component 113 determines that a valley check for a read margin is complete in response to the number of bits with a value ‘1’ in correct sense deltas equaling 0 for the current sense read level. For example, read level determination component 113 performs sensing operations at fourth read level 240 and determines to stop performing sense operations for increasing read levels for the read margin after determining that there are no bits with a value ‘1’ for the current correct sense delta 248. Accordingly, read level determination component 113 scans the read margin until the entirety of the previous logic state has been fully scanned.

In some embodiments, in response to determining that a valley check for a read margin is complete, read level determination component 113 calculates an optimal read level for the read margin. For example, read level determination component 113 determines a total error count for each of first read level 210, second read level 220, third read level 230, and fourth read level 240 and selects the read level with the smallest total error count.

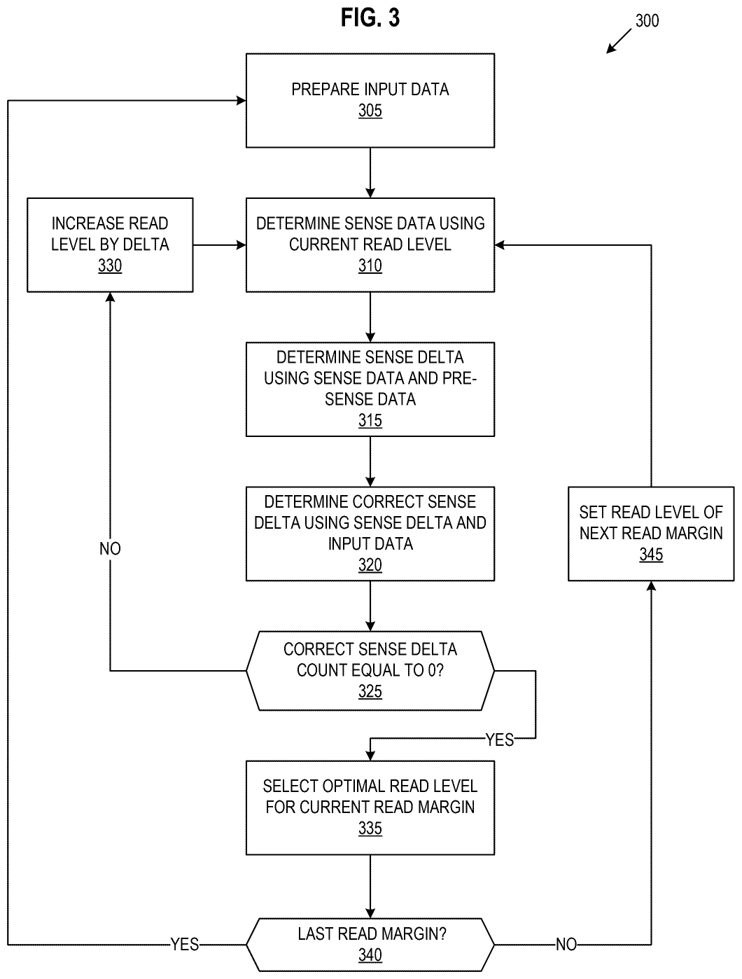

FIG. 3 is a flow diagram of an example method 300 to determine optimal read levels using reference data, in accordance with some embodiments of the present disclosure. The method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 300 is performed by the read level determination component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 305, the processing device prepares the input data. For example, read level determination component 113 reads reference data from an OTP area of a memory device (e.g., memory device 130 of FIG. 1). In some embodiments, the processing device receives the input data from a host system. For example, read level determination component 113 receives the input data from host system 120.

In some embodiments, the processing device prepares the input data by performing an encoding on the reference data. For example, the reference data read from the OTP area and/or received from the host system is not scrambled and/or ECC encoded. The reference data stored in the memory device to be scanned, however can be scrambled and/or ECC encoded. The processing device scans the memory without reading out through a decoder, the values read from memory are scrambled and/or encoded. In order to properly compare the reference data (e.g., read from the OTP area) with the corresponding data stored in the memory device, read level determination component 113 performs an encoding and/or scrambling on the reference data (e.g., read from the OTP area).

At operation 310, the processing device determines sense data using a current read level. For example, read level determination component 113 performs a sense operation for the current read level and determines the sense data as explained with reference to FIG. 2.

At operation 315, the processing device determines a sense delta using the sense data and pre-sense data. For example, read level determination component 113 determines sense delta 216 by performing a logical XOR operation on pre-sense data 212 and sense data 214 as described with reference to FIG. 2. In some embodiments, the processing device uses an input position to determine the sense delta. For example, read level determination component 113 uses input position 204 to mask irrelevant memory cells when determining sense delta 216.

At operation 320, the processing device determines a correct sense delta using sense delta and the input data. For example, read level determination component 113 determines correct sense delta 218 performs a logical AND operation using input data 202 and sense delta 216 as described with reference to FIG. 2.

At operation 325, the processing device determines whether the current correct sense delta count is equal to 0. For example, read level determination component 113 determines a count of the number of ‘1’s in the correct sense delta for the current read level. If the processing device determines that the correct sense delta count is equal to 0, the method 300 proceeds to operation 335. If the processing device determines that the correct sense delta count is not equal to 0, the method 300 proceeds to operation 330. Further details with regard to determining whether the current correct sense delta count is equal to 0 are described with reference to FIG. 2.

At operation 330, the processing device increases the read level by delta. For example, read level determination component 113 increases the read level for the current margin by a predetermined amount. In some embodiments, a correct sense delta count being equal to 0 indicates the entirety of the first logic state has been scanned. As long as the correct sense delta count is greater than 0, the processing device continues to perform a valley check on the read margin. For example, read level determination component 113 increases the read level by delta (e.g., from first read level 210 to second read level 220) and performs a sense operation on the read margin using the increased read level. Further details with regard to increasing the read level by delta are described with reference to FIG. 2.

At operation 335, the processing device selects an optimal read level for the current read margin. For example, determining the correct sense delta count equals 0 indicates the entirety of the current logic state has been scanned. The processing device calculates a total error count for each of the read levels evaluated and selects the optimal read level as the read level with the lowest total error count. Further details with regard to selecting the optimal read level are described with reference to FIG. 2.

At operation 340, the processing device determines whether the current read margin is the last read margin for the memory cells. For example, the selection of an optimal read level for reading memory cells programmed to the L0 logic state may not provide sufficient information for setting optimal read levels for other logic states. Selecting an optimal read level for another logic state, e.g., L4, however, may provide sufficient information for setting optimal read levels for the other logic states (e.g., L1-L3 and L5-L7). In some embodiments, the processing device iterates through all read margins for the memory cells. If the processing device determines the current read margin is the last read margin, the method 300 returns to operation 305 and waits for the next required valley check. If the processing device determines the current read margin is not the last read margin, the method 300 proceeds to operation 345.

At operation 345, the processing device sets the read level of the next read margin. For example, read level determination component 113 sets the first read level of the next read margin to an initial value. In some embodiments, the processing device sets the initial read level for the next read margin to the last optimal read level for the next read margin (e.g., based on previous valley checks for the next read margin). In some embodiments, the processing device sets the initial read level for the next read margin to a predetermined default value.

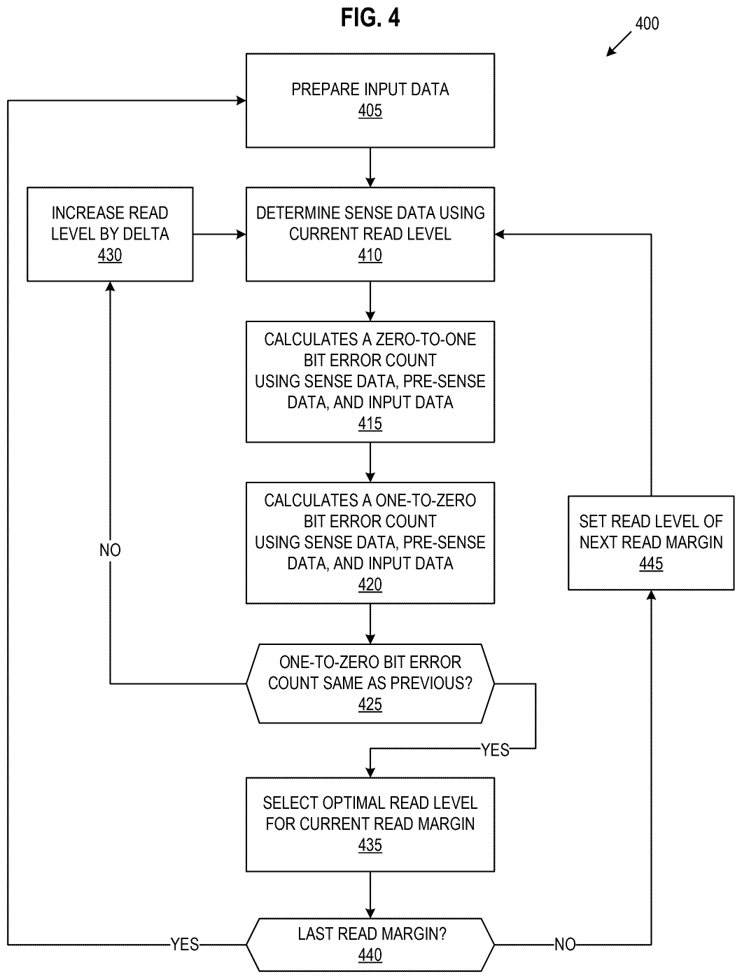

FIG. 4 is another flow diagram of an example method 400 to determine optimal read levels using reference data, in accordance with some embodiments of the present disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by the read level determination component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 405, the processing device prepares the input data. For example, read level determination component 113 reads reference data from an OTP area of a memory device (e.g., memory device 130 of FIG. 1). In some embodiments, the processing device prepares the input data by performing an encoding on the reference data. Further details with regard to preparing the input data are described with reference to FIG. 3.

At operation 410, the processing device determines sense data using a current read level. For example, read level determination component 113 performs a sense operation for the current read level and determines the sense data as explained with reference to FIG. 2.

At operation 415, the processing device calculates a zero-to-one bit error count for the current read level using the sense data, pre-sense data, and input data. The zero-to-one bit error count indicates the number of bits that are 0 in the input data but 1 in the sense data. In one embodiment, when performing a valley check on the L0 to L1 valley for a TLC memory, the zero-to-one bit error count indicates the number of memory cells programmed as input data in the L1 logic state being incorrectly sensed as being in the L0 logic state at the current read level. In some embodiments, the processing device calculates the zero-to-one bit error count using input position (e.g., input position 204 of FIG. 2). For example, the processing device uses input position to indicate which memory cells should be considered when calculating the zero-to-one bit error count. In one embodiment, the processing device calculates the zero-to-one bit error count according to the following equation:

$$\sum ( ( InputPosition \& {PreSenseData}^{′} ) \& ( ReferenceData \hat{} SenseData ) \& SenseData ) ,$$

where Σ indicates the sum of the bits, PreSenseData′ is the inverse of pre-sense data, & indicates an and operation, and \hat{ } indicates an exclusive-or operation. Like the other logical operations described herein, the processing device can use a hardware accelerator of the memory subsystem to perform the logical operations and corresponding sum.

At operation 420, the processing device calculates a one-to-zero bit error count for the current read level using the sense data, pre-sense data, and input data. The one-to-zero bit error count indicates the number of bits that are 1 in the input data but 0 in the sense data. In one embodiment, when performing a valley check on the L0 to L1 valley for a TLC memory, the one-to-zero bit error count indicates the number of memory cells programmed as input data in the L0 logic state that are being incorrectly attributed to L1 (e.g., L0 memory cells that are not sensed at the current read level). In some embodiments, the processing device calculates the one-to-zero bit error count using input position (e.g., input position 204 of FIG. 2). For example, the processing device uses input position to indicate which memory cells should be considered when calculating the one-to-zero bit error count. In one embodiment, the processing device calculates the one-to-zero bit error count according to the following equation:

$$\sum ( ( InputPosition \& {PreSenseData}^{′} ) \& ( ReferenceData \hat{} SenseData ) \& {SenseData}^{′} ) ,$$

where Σ indicates the sum of the bits, PreSenseData′ is the inverse of pre-sense data, SenseData′ is the inverse of sense data & indicates an and operation, and \hat{ } indicates an exclusive-or operation. In some embodiments, the processing device stores the one-to-zero bit error count for determining when to end the valley check for the current read margin.

In some embodiments, the processing device calculates a total error count for the current read level. For example, read level determination component 113 adds the values of the zero-to-one bit error count and the one-to-zero bit error count to get a total error count. Continuing the example above, the total error count reflects the sum of the number of L1 memory cells incorrectly sensed as belonging to L0 and the number of L0 memory cells incorrectly sensed as belonging to L1. In some embodiments, the processing device stores the total error count for use when selecting the optimal read level.

At operation 425, the processing device determines whether the one-to-zero bit error count is the same as the one-to-zero bit error count for the previous read level. For example, read level determination component 113 determines whether the one-to-zero bit error count for the current read level is the same as the one-to-zero bit error count for the previous read level. Referring again to the example illustrated in FIG. 2, more of the memory cells in the first logic state (e.g., L0) are sensed with each increase in read level until reaching a read level that correctly senses all memory cells programmed to the first logic state. In other words, as the processing device senses more of the memory cells in the first logic state, the one-to-zero bit error count reduces since the number of memory cells that should be ‘111’ and are correctly sensed as ‘111’ (rather than being attributed to ‘110’) increases. In some embodiments, the processing device stops the valley check for the current read margin when the one-to-zero bit error count is the same as the one-to-zero bit error count for the previous read level because this indicates the entirety of the first logic state has been scanned. If the processing device determines that the one-to-zero bit error count for the current read level is the same as the one-to-zero bit error count for the previous read level, the method 400 proceeds to operation 435. If the processing device determines that the one-to-zero bit error count for the current read level is not the same as the one-to-zero bit error count for the previous read level, the method proceeds to operation 430.

At operation 430, the processing device increases the read level by delta. For example, read level determination component 113 increases the read level for the current margin by a predetermined amount and continues to perform a valley check on the current read margin. Further details with regard to increasing the read level by delta are described with reference to FIGS. 2 and 3.

At operation 435, the processing device selects the optimal read level for the current read margin. For example, read level determination component 113 selects an optimal read level for the current read margin using the total error counts for each of the read levels in the valley check. In some embodiments, read level determination component 113 selects the optimal read level as the read level with the lowest total error count. For example, read level determination component 113 selects the optimal read level as the read level with the lowest sum of zero-to-one bit error count and one-to-zero bit error count.

At operation 440, the processing device determines whether the current read margin is the last read margin for the memory cells. For example, the selection of an optimal read level for reading memory cells programmed to the L0 logic state may not provide sufficient information for setting optimal read levels for other logic states. Selecting an optimal read level for another logic state, e.g., L4, however, may provide sufficient information for setting optimal read levels for the other logic states (e.g., L1-L3 and L5-L7). In some embodiments, the processing device iterates through all read margins for the memory cells. If the processing device determines the current read margin is the last read margin, the method 400 returns to operation 405 and waits for the next required valley check. If the processing device determines the current read margin is not the last read margin of the current bit, the method 400 proceeds to operation 445.

At operation 445, the processing device sets the read level of the next read margin. For example, read level determination component 113 sets the first read level of the next read margin to an initial value. In some embodiments, the processing device sets the initial read level for the next read margin to the last optimal read level for the next read margin (e.g., based on previous valley checks for the next read margin). In some embodiments, the processing device sets the initial read level for the next read margin to a predetermined default value.

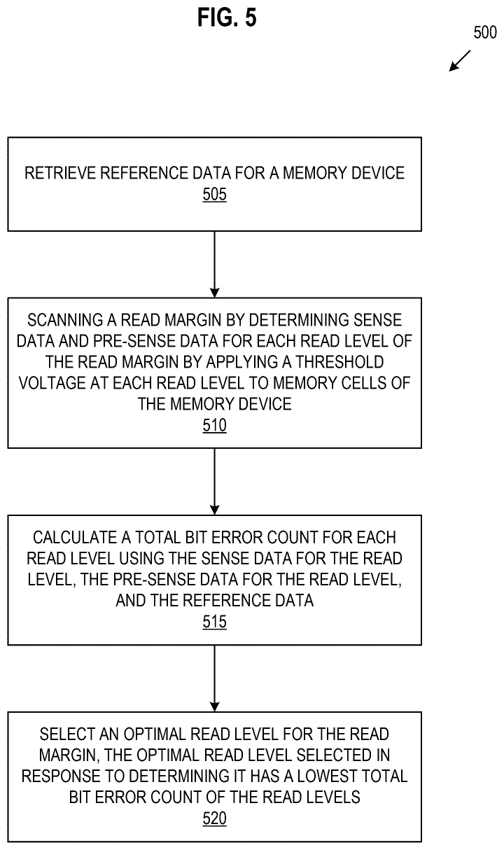

FIG. 5 is a flow diagram of an example method 500 to determine optimal read levels using reference data, in accordance with some embodiments of the present disclosure. The method 500 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 is performed by the read level determination component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 505, the processing device retrieves reference data for a memory device. For example, read level determination component 113 reads input data 202 from an OTP memory area of memory device 130. In some embodiments, the processing device receives the reference data from a host system. For example, read level determination component 113 receives input data 202 from host system 120. Further details regarding retrieving the reference data are described with reference to FIGS. 3 and 4.

At operation 510, the processing device scans a read margin by determining sense data for each read level for a read margin by applying a threshold voltage at each read level to memory cells of the memory device. For example, read level determination component 113 applies increasing read levels for a read margin as explained with reference to FIGS. 2, 3, and 4. In some embodiments, the processing device determines to stop scanning the read margin (e.g., stop applying increasing read levels) in response to a trigger. For example, read level determination component 113 determines to stop scanning the read margin in response to determining that the correct sense delta for a read level is equal to 0 as explained with reference to FIGS. 2 and 3. As an alternative example, read level determination component 113 determines to stop scanning the read margin in response to determining that consecutive read levels have the same one-to-zero bit error count as explained with reference to FIG. 4. Further details regarding scanning a read margin are described with reference to FIGS. 2, 3, and 4.

At operation 515, the processing device calculates a total error count for each read level using the sense data for the read level, the pre-sense data for the read level, and the reference data. For example, read level determination component 113 calculates a total error count using input data 202, the sense delta for the current read level, and the correct sense delta for the current read level. As an alternative example, read level determination component 113 calculates a total error count for a read level using the zero-to-one bit error count and the one-to-zero bit error count for that read level. Further details regarding calculating a cumulative error count for each read level are described with reference to FIGS. 2, 3, and 4.

At operation 520, the processing device selects an optimal read level for the read margin in response to determining that the optimal read level has a lowest total error count of the read levels. Further details regarding selecting an optimal read level for the read margin are described with reference to FIGS. 2, 3, and 4.

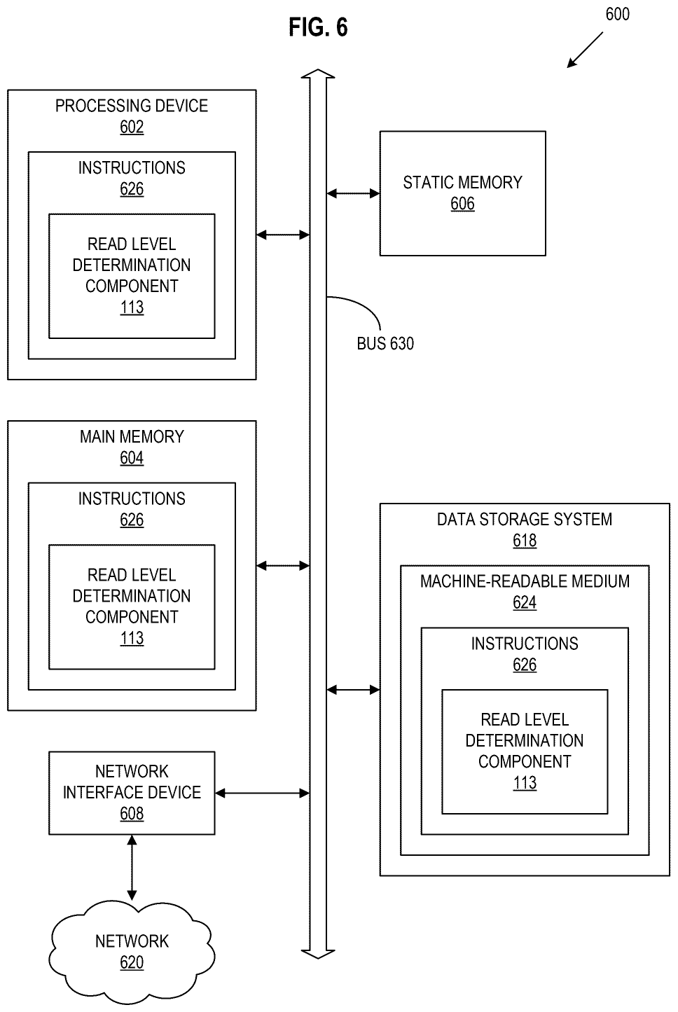

FIG. 6 illustrates an example machine of a computer system 600 within which a set of instructions for causing the machine to perform any one or more of the methodologies discussed herein can be executed. In some embodiments, the computer system 600 can correspond to a host system (e.g., the host system 120 of FIG. 1) that includes, is coupled to, or utilizes a memory subsystem (e.g., the memory subsystem 110 of FIG. 1) or can be used to perform the operations of a controller (e.g., to execute an operating system to perform operations corresponding to the read level determination component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a smart device, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random-access memory (DRAM) such as synchronous DRAM (SDRAM) or Rambus DRAM (RDRAM), etc.), a static memory 606 (e.g., flash memory, static random-access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein. The computer system 600 can further include a network interface device 608 to communicate over the network 620.

The data storage system 618 can include a machine-readable storage medium 624 (also known as a computer-readable medium) on which is stored one or more sets of instructions 626 or software embodying any one or more of the methodologies or functions described herein. The instructions 626, constituting machine-readable storage media, can also reside, completely or at least partially, within the main memory 604 and/or within the processing device 602 during execution thereof by the computer system 600, the main memory 604 and the processing device 602. The machine-readable storage medium 624, data storage system 618, and/or main memory 604 can correspond to the memory subsystem 10 of FIG. 1.

In one embodiment, the instructions 626 include instructions to implement functionality corresponding to a read level determination component (e.g., read level determination component 113 of FIG. 1). While the machine-readable storage medium 624 is shown in an example embodiment to be a single medium, the term “machine-readable storage medium” should be taken to include a single medium or multiple media that store the one or more sets of instructions (e.g., instructions 626). The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. For example, a computer system or other data processing system, such as the controller 115, may carry out the computer-implemented methods 300, 400, and 500 in response to its processor executing a computer program (e.g., a sequence of instructions) contained in a memory or other non-transitory machine-readable storage medium. Such a computer program can be stored in a computer readable storage medium, such as, but not limited to, any type of disk including floppy disks, optical disks, CD-ROMs, and magnetic-optical disks, read-only memories (ROMs), random-access memories (RAMs), EPROMs, EEPROMs, magnetic or optical cards, or any type of media suitable for storing electronic instructions coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method comprising:
retrieving reference data for a memory device;
scanning a read margin by determining sense data and pre-sense data for each read level of a plurality of read levels for the read margin by applying a threshold voltage at each read level to a plurality of cells of the memory device, wherein the pre-sense data for a read level of the plurality of read levels is the sense data for a previous read level;
calculating, by the memory device, a total error count for each read level using the sense data for the plurality of cells at the read level, the pre-sense data for plurality of cells at the read level, and the reference data; and
selecting an optimal read level for the read margin, wherein the optimal read level is selected in response to comparing the total error count for each read level and determining a read level that has a lowest total error count of the plurality of read levels.

2. The method of claim 1, further comprising:
receiving an array address for the memory device; and
determining the plurality of cells using the array address.

3. The method of claim 1, further comprising:
determining to stop scanning the read margin in response to a trigger, wherein selecting the optimal read level is in response to the determination to stop scanning the read margin.

4. The method of claim 3, further comprising:
determining a sense delta for each read level using the sense data and the pre-sense data for the read level, wherein the sense delta for the read level indicates differences between the sense data and the pre-sense data for the read level; and
determining a correct sense delta for each read level using the sense delta and the reference data, wherein the correct sense delta for each read level indicates a number of correctly sensed memory cells in the sense delta for that read level and wherein the trigger comprises determining that the correct sense delta for a read level is equal to zero.

5. The method of claim 4, wherein calculating the total error count for each read level comprises:
determining a final correct count using the reference data, wherein the final correct count is a number of memory cells in the reference data belonging to a logic state for the read margin;
determining a correct sense count using the correct sense delta for the read level, wherein the correct sense count is a number of memory cells correctly sensed as belonging to the logic state for the read level;
determining an incorrect sense count using the sense delta for the read level and the correct sense delta for the read level, wherein the incorrect sense count is a number of memory cells incorrectly sensed as belonging to the logic state for the read level; and
calculating the total error count using the final correct count, the correct sense count, and the incorrect sense count.

6. The method of claim 3, further comprising:
calculating a one-to-zero bit error count for each read level using the sense data for the read level, the pre-sense data for the read level, and the reference data, wherein the trigger comprises determining that one-to-zero bit error counts for consecutive read levels of the plurality of read levels are equal.

7. The method of claim 6, further comprising:
calculating a zero-to-one bit error count for each read level using the sense data for the read level, the pre-sense data for the read level, and the reference data, wherein calculating the total error count for each read level comprises summing the one-to-zero bit error count for the read level with the zero-to-one bit error count for the read level.

8. A non-transitory computer-readable storage medium comprising instructions that, when executed by a processing device, cause the processing device to:
retrieve reference data for a memory device;
scan a read margin by determining sense data and pre-sense data for each read level of a plurality of read levels for the read margin by applying a threshold voltage at each read level to a plurality of cells of the memory device, wherein the pre-sense data for a read level of the plurality of read levels is the sense data for a previous read level;
calculate, by the memory device, a total error count for each read level using the sense data for the plurality of cells at the read level, the pre-sense data for plurality of cells at the read level, and the reference data; and
select an optimal read level for the read margin, wherein the optimal read level is selected in response to comparing the total error count for each read level and determining a read level that has a lowest total error count of the plurality of read levels.

9. The non-transitory computer-readable storage medium of claim 8, wherein the processing device is further to:
receive an array address for the memory device; and
determine the plurality of cells using the array address.

10. The non-transitory computer-readable storage medium of claim 8, wherein the processing device is further to:
determine to stop scanning the read margin in response to a trigger, wherein selecting the optimal read level is in response to the determination to stop scanning the read margin.

11. The non-transitory computer-readable storage medium of claim 10, wherein the processing device is further to:
determine a sense delta for each read level using the sense data and the pre-sense data for the read level, wherein the sense delta for the read level indicates differences between the sense data and the pre-sense data for the read level; and
determine a correct sense delta for each read level using the sense delta and the reference data, wherein the correct sense delta for each read level indicates a number of correctly sensed memory cells in the sense delta for that read level and wherein the trigger comprises determining that the correct sense delta for a read level is equal to zero.

12. The non-transitory computer-readable storage medium of claim 11, wherein calculating the total error count for each read level comprises:
determining a final correct count using the reference data, wherein the final correct count is a number of memory cells in the reference data belonging to a logic state for the read margin;
determining a correct sense count using the correct sense delta for the read level, wherein the correct sense count is a number of memory cells correctly sensed as belonging to the logic state for the read level;
determining an incorrect sense count using the sense delta for the read level and the correct sense delta for the read level, wherein the incorrect sense count is a number of memory cells incorrectly sensed as belonging to the logic state for the read level; and
calculating the total error count using the final correct count, the correct sense count, and the incorrect sense count.

13. The non-transitory computer-readable storage medium of claim 10, wherein the processing device is further to:
calculate a one-to-zero bit error count for each read level using the sense data for the read level, the pre-sense data for the read level, and the reference data, wherein the trigger comprises determining that one-to-zero bit error counts for consecutive read levels of the plurality of read levels are equal.

14. The non-transitory computer-readable storage medium of claim 13, wherein the processing device is further to:
calculate a zero-to-one bit error count for each read level using the sense data for the read level, the pre-sense data for the read level, and the reference data, wherein calculating the total error count for each read level comprises summing the one-to-zero bit error count for the read level with the zero-to-one bit error count for the read level.

15. A system comprising:
a plurality of memory devices; and
a processing device, operatively coupled with the plurality of memory devices, to:
retrieve reference data for a memory device;
scan a read margin by determining sense data and pre-sense data for each read level of a plurality of read levels for the read margin by applying a threshold voltage at each read level to a plurality of cells of the memory device, wherein the pre-sense data for a read level of the plurality of read levels is the sense data for a previous read level;
determine to stop scanning the read margin in response to a trigger;
calculate, by the memory device, a total error count for each read level using the sense data for the plurality of cells at the read level, the pre-sense data for plurality of cells at the read level, and the reference data; and
select an optimal read level for the read margin in response to determining to stop scanning the read margin, wherein the optimal read level is selected in response to comparing the total error count for each read level and determining a read level that has a lowest total error count of the plurality of read levels.

16. The system of claim 15, wherein the processing device is further to:
receive an array address for the memory device; and
determine the plurality of cells using the array address.

17. The system of claim 15, wherein the processing device is further to:
determine a sense delta for each read level using the sense data and the pre-sense data for the read level, wherein the sense delta for the read level indicates differences between the sense data and the pre-sense data for the read level; and
determine a correct sense delta for each read level using the sense delta and the reference data, wherein the correct sense delta for each read level indicates a number of correctly sensed memory cells in the sense delta for that read level and wherein the trigger comprises determining that the correct sense delta for a read level is equal to zero.

18. The system of claim 17, wherein calculating the total error count for each read level comprises:
determining a final correct count using the reference data, wherein the final correct count is a number of memory cells in the reference data belonging to a logic state for the read margin;
determining a correct sense count using the correct sense delta for the read level, wherein the correct sense count is a number of memory cells correctly sensed as belonging to the logic state for the read level;
determining an incorrect sense count using the sense delta for the read level and the correct sense delta for the read level, wherein the incorrect sense count is a number of memory cells incorrectly sensed as belonging to the logic state for the read level; and
calculating the total error count using the final correct count, the correct sense count, and the incorrect sense count.

19. The system of claim 15, wherein the processing device is further to:
calculate a one-to-zero bit error count for each read level using the sense data for the read level, the pre-sense data for the read level, and the reference data, wherein the trigger comprises determining that one-to-zero bit error counts for consecutive read levels of the plurality of read levels are equal.

20. The system of claim 19, wherein the processing device is further to:
calculate a zero-to-one bit error count for each read level using the sense data for the read level, the pre-sense data for the read level, and the reference data, wherein calculating the total error count for each read level comprises summing the one-to-zero bit error count for the read level with the zero-to-one bit error count for the read level.
